(19) United States
(12) Patent Application Publication
(10) Pub. No.: US 2013/0279142 A1
(43) Pub. Date: Oct. 24, 2013

(54) HOUSING AND ELECTRONIC DEVICE USING SAME

(71) Applicants: FU TAI HUA INDUSTRY (SHENZHEN) CO., LTD., (US); HON HAI PRECISION INDUSTRY CO., LTD., (US)

(72) Inventor: HUI WANG, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 13/855,861

(22) Filed: Apr. 3, 2013

(30) Foreign Application Priority Data
Apr. 20, 2012 (CN) 201210116946.5

(51) Int. Cl. H05K 7/02; H05K 5/03

(52) U.S. Cl. CPC H05K 7/02; H05K 5/03
USPC 361/809; 312/223.1

(57) ABSTRACT

A housing includes a bottom shell and a plurality of protection blocks. The bottom shell includes a bottom wall, a peripheral wall extending from a periphery of the bottom wall, and a support wall extending from a side surface of the peripheral wall toward the interior of the housing. The support wall includes a plurality of corners. Each of the plurality of corners encloses a protection groove holding a protection block, thus building protection against impacts within the existing profile of the housing, instead of the protection being attached to the exterior of the housing.

### BACKGROUND

1. Technical Field

The present disclosure relates to device housings and particularly, to a housing of an electronic device.

2. Description of the Related Art

An electronic device often includes a bottom shell, a support frame, and a display. The support frame is fixed on the bottom shell. The screen is fixed on the support frame. However, upon an impact, the display screen and the bottom shell can be easily damaged due to insufficient structural strength at the corners of the display screen and the bottom shell. A plurality of protection blocks is fixed outside of the corners by fasteners to absorb impacts against the corners. However, such protection blocks increase a size of the electronic device and reduce the aesthetic appearance of the electronic device.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 is an assembled, isometric view of one embodiment of an electronic device.

FIG. 2 is an exploded, isometric view of the electronic device shown in FIG. 1.

FIG. 3 is an enlarged view of a circled portion III in FIG. 2.

FIG. 4 is an enlarged, assembled, isometric view of the circled portion III in FIG. 2.

FIG. 5 is a partial, cross sectional view of the electronic device taken along line V-V of FIG. 1.

### DETAILED DESCRIPTION

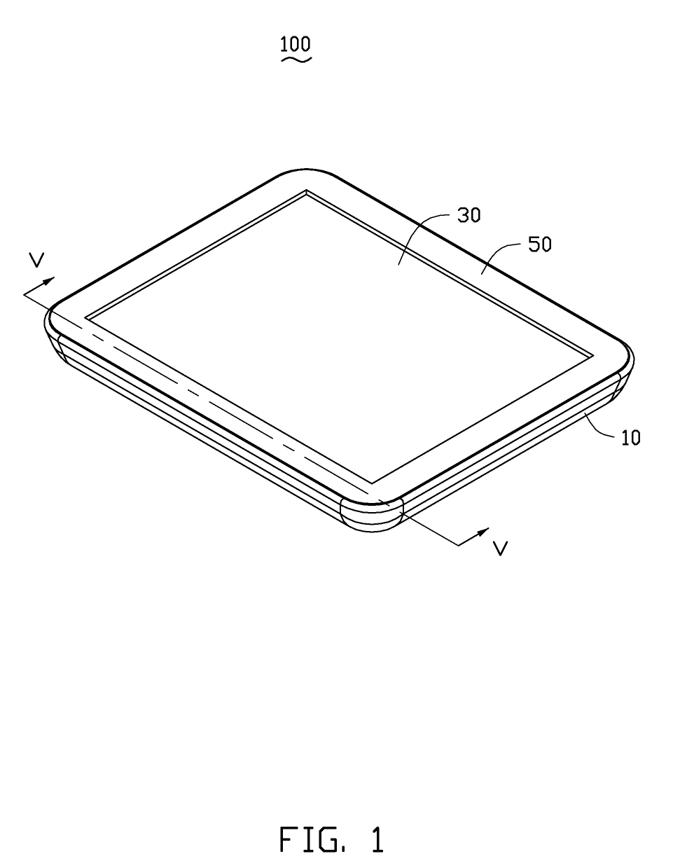

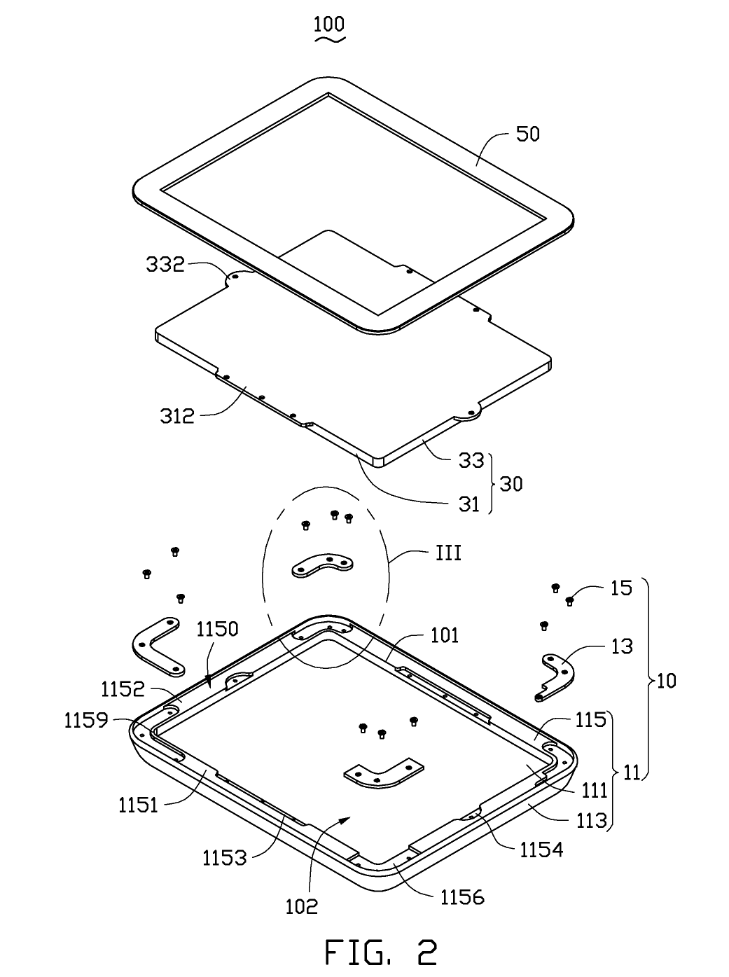

FIGS. 1 and 2 show one embodiment of an electronic device 100. The electronic device 100 includes a housing 10, a display panel 30, a frame 50, and other various functional modules (not shown) received in the housing 10. The display panel 30 and the frame 50 are mounted on the housing 10. The other various functional modules implement a variety of functions. For simplicity, only the housing 10, the display panel 30, and the frame 50 are described in detail. The electronic device 100 can be a tablet computer, a mobile phone, a digital photo frame or a liquid crystal display. In an illustrated embodiment, the electronic device 100 is a tablet computer.

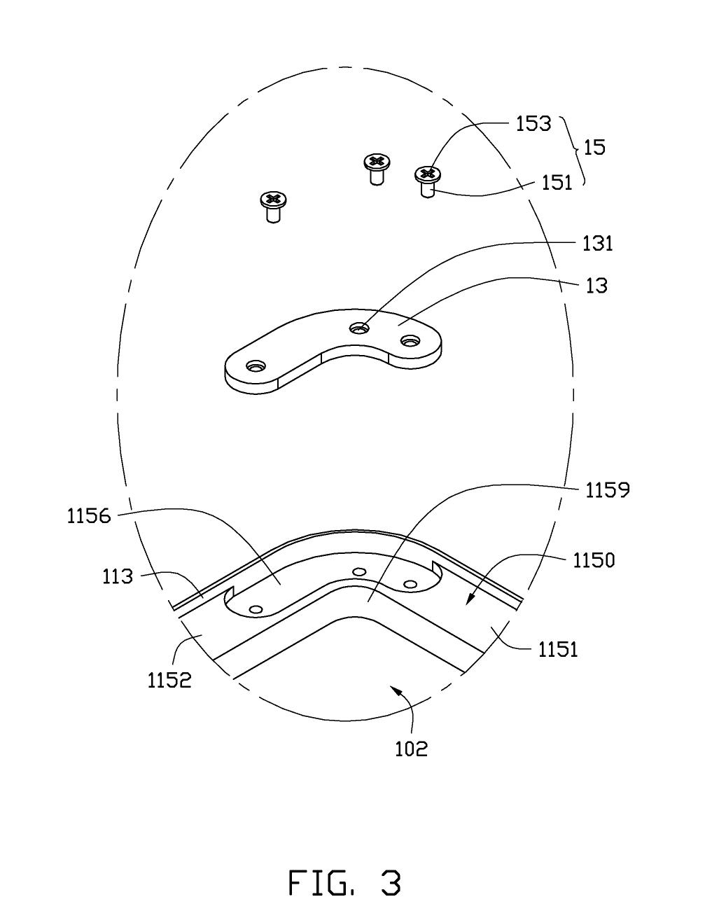

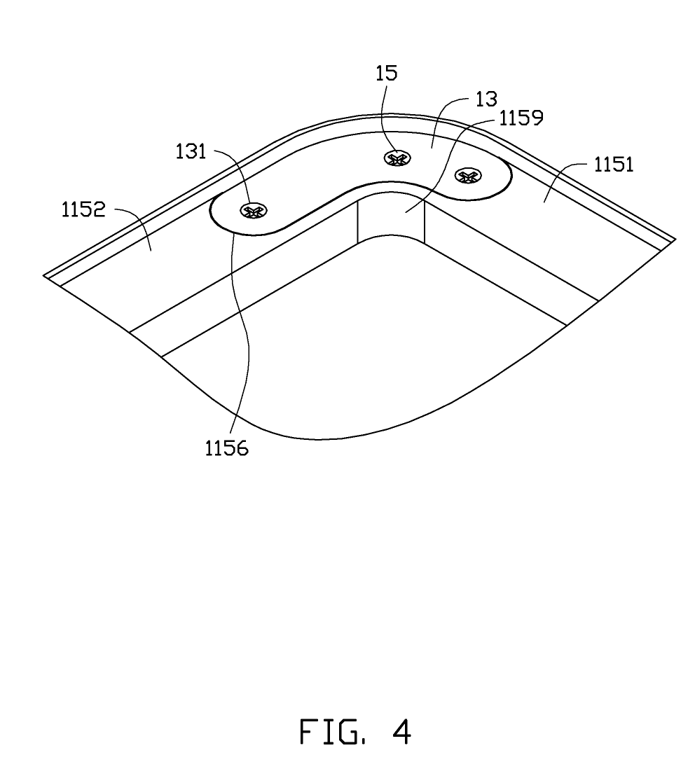

Referring also to FIGS. 2 through 4, the housing 10 includes a bottom shell 11, a plurality of protection blocks 13 positioned at corners of the bottom shell 11, and a plurality of fasteners 15 to fix the protection blocks 13 to the bottom shell 11. In the illustrated embodiment, the bottom shell 11 is made of metal, such as aluminum alloy, magnesium alloy, titanium alloy, and stainless steel, and is formed by punching. The bottom shell 11 includes a bottom wall 111, a peripheral wall 113, and a support wall 115. The peripheral wall 113 substantially perpendicularly extends from a periphery of the bottom wall 111. The support wall 115 extends from side surfaces of the peripheral wall 113 toward the interior of the housing 10. In the illustrated embodiment, the bottom wall 111 is substantially rectangular. A connecting portion of the peripheral wall 113 and the bottom wall 111 is substantially curved to add to the aesthetics. The support wall 115 is substantially rectangular and frame-like. The support wall 115, the peripheral wall 113, and the bottom wall 111 cooperatively form a receiving space 102 to receive the functional modules, through an opening 101.

In the illustrated embodiment, a height of the peripheral wall 113 is greater than a height of the support wall 115 along a direction substantially perpendicular to the bottom wall 111, such that the peripheral wall 113 and the support wall 115 cooperatively define a receiving groove 1150 around the opening 101, to receive the frame 50. The support wall 115 includes two first end surfaces 1151 away from the bottom wall 111 and two second end surfaces 1152 away from the bottom wall 111. Opposite ends of each first end surface 1151 are substantially perpendicularly connected to one end of each second surface 1152. A first mounting groove 1153 is defined in a substantially middle portion of each first end surface 1151 facing the receiving space 102. The first mounting groove 1153 is substantially trapezoidal. A second mounting groove 1154 is defined in a substantially middle portion of each second end surface 1152 facing the receiving space 102. The second mounting groove 1154 is substantially arcuate. A corner 1159 formed between each first end surface 1151 and each second end surface 1152 defines a protection groove 1156 for receiving the protection blocks 13. The protection groove 1156 is substantially L-shaped. In the illustrated embodiment, there are four corners 1159 each defining a protection groove 1156 for receiving a protection block 13, in a top surface away from the bottom wall 111. A plurality of fixing holes 1157 is defined in a bottom surface of the protection groove 1156. In other embodiments, a shape of the bottom shell 11 is variable, the quantity of the corners 1159, the quantity of the protection grooves 1156, and the quantity of the protection blocks 13 can be changed accordingly.

Each protection block 13 is substantially L-shaped, and is engaged in the protection groove 1156. A plurality of engaging holes 131 is defined in the protection block 13, according to the fixing holes 1157 in the support frame 115. In the illustrated embodiment, a thickness of each protection block 115 is substantially equal to a depth of each protection groove 1156, such that a top surface of the protection block 115 is coplanar with the first end surface 1151 and the second end surface 1152. Each protection block 115 is made of stainless steel or tungsten steel.

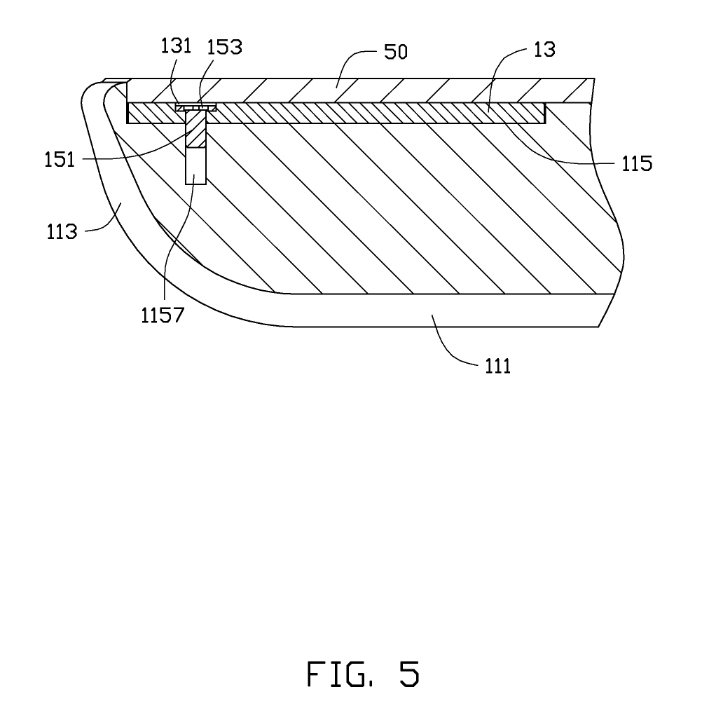

Referring also to FIG. 5, each fastener 15 includes a fixing portion 151 and an end portion 153 connected to the fixing portion 151. The fixing portion 151 passes through the engaging hole 131 of the protection block 13, to be securely mounted in the fixing hole 1157 of the support wall 115. The end portion 153 is wholly received in the engaging hole 131 of the protection block 13, such that a top surface of the end portion 513 is not higher than coplanar with a top surface of the protection block 13. A quantity of the fasteners 15 is same as a quantity of the fixing holes of the support wall 115. The fasteners 15 can be screws, pins, or rivets. In other embodiments, the protection blocks 13 can be fixed to the bottom shell 11 by latching, interference fitting, or other means.

The display panel 30 is substantially a rectangular plate, and is securely mounted on the support wall 115. The display panel 30 includes two first sidewalls 31, two second sidewall 33, two first extending portion 312, and two second extending portions 332. Opposite ends of each first sidewall 31 are each substantially perpendicularly connected to one end of one second sidewall 33. Each first extending portion 312 extends from a substantially middle portion of one first sidewall 31 according to the first mounting groove 1153. Each second extending portion 332 extends from a substantially middle portion of one second sidewall 33 according to the second mounting groove 1154. Top surfaces of the first sidewalls 31 and two second sidewall 33 are coplanar with the first end surfaces 1151 and the second end surfaces 1152. In other embodiments, the quantity of the first mounting grooves 1153 or of the second mounting grooves 1154 can be changed, and the quantity of the first extending portions 312 or of the second extending portions 332 can be changed accordingly.

The frame 50 is substantially rectangular. A size of the frame 50 is substantially same as a size of the receiving groove 1150. The frame 50 is securely received in the receiving groove 1150 above the protection blocks 13, the first extending portions 312, and the second extending portions 332, as the base structure on which the display panel 30 is mounted. The frame 50 is made of plastic.

In assembly, the protection blocks 13 are firstly attached to the support wall 115 in the receiving grooves 1156 by adhesive, and then the fixing portions 151 pass through the engaging holes 131 of the protection blocks 13 to be securely mounted in the fixing holes 1157 of the support wall 115. Secondly, the first extending portions 312 and the second extending portions 332 are securely mounted in the first mounting grooves 1153 and the second mounting grooves 1154 respectively, such that the display panel 30 is positioned on the support wall 15. Lastly, the frame 50 is securely fixed in the receiving groove 1150 above the base structure of the protection blocks 13, the first extending portions 312, and the second extending portions 332.

When the electronic device 100 is violently impacted, for example, by being dropped, the protection blocks 13 absorb all the external force, such that the housing 10 and the display panel 30 are protected from damage by the protection blocks 13. The protection blocks 13 being fixed between the frame 50 and the bottom shell 11 save and reduce the occupied volume of the electronic device 100, such that the electronic device 100 can be made thinner. In addition, because the top surface of the protection block 115 is coplanar with the first end surface 1151 and the second end surface 1152, an assembly process is not prejudiced or negatively affected, such that a yield of the electronic device 100 is improved.

The side plates 12 can also extend perpendicular to the bottom plate 11. The elongated grooves 23 can also be omitted, where the support frame 20 is actually fixed to the bottom shell 10 by plastic welding or hook structures. The adhesive grooves 32 of the protection blocks 30 can also be omitted, where the protection blocks 30 are actually fixed in the bottom shell 10 by plastic welding.

While the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure as defined by the appended claims.

What is claimed is:

1. A housing comprising:
a bottom shell comprising a bottom wall, a peripheral wall extending from a periphery of the bottom wall, and a support wall extending from a side surface of the peripheral wall toward an interior of the housing, wherein the support wall comprises a plurality of corners, each of the plurality of corners comprises a top surface away from the bottom wall, the top surface defines a protection groove; and
a plurality of protection blocks, each of the plurality of protection blocks being securely fixed to the support wall in the protection groove.

2. The housing of claim 1, wherein the protection groove is substantially L-shaped, and each of the plurality of protection blocks is accordingly shaped relative to the protection groove.

3. The housing of claim 1, wherein a plurality of mounting grooves is defined in the support wall.

4. The housing of claim 1, wherein a height of the peripheral wall is greater than a height of the support wall along a direction substantially perpendicular to the bottom wall, such that the peripheral wall and the support wall cooperatively define a receiving groove.

5. The housing of claim 1, wherein the bottom wall is substantially rectangular, the support wall comprises four corners, each of the four corners defines the protection groove, the housing comprises four protection blocks, and each of the four protection blocks is securely fixed to the support wall in the protection groove.

6. The housing of claim 1, wherein a plurality of fixing holes is defined in a bottom surface of the protection groove, a plurality of engaging holes is defined in each of the plurality of protection blocks, the housing further comprises a plurality of fasteners, each of the plurality of fasteners comprises a fixing portion and an end portion connected to the fixing portion, the fixing portion is configured to pass through each of the plurality of engaging holes and to be securely mounted in each of the plurality of fixing holes.

7. The housing of claim 6, wherein the end portion is configure to be entirely received in each of the plurality of engaging holes.

8. The housing of claim 1, wherein a thickness of each of the plurality of protection blocks is substantially equal to a depth of the protection groove.

9. An electronic device, comprising:
a housing comprising:
a bottom shell comprising a bottom wall, a peripheral wall extending from a periphery of the bottom wall, and a support wall extending from a side surface of the peripheral wall toward an interior of the housing, wherein the support wall comprises a plurality of corners, each of the plurality of corners comprises a top surface away from the bottom wall, the top surface defines a protection groove; and
a plurality of protection blocks, each of the plurality of protection blocks being securely fixed to the support wall in the protection groove; and
a display panel securely positioned on the support wall above the plurality of protection blocks.

10. The electronic device of claim 9, wherein the protection groove is substantially L-shaped, and each of the plurality of protection blocks is substantially L-shaped corresponding to the protection groove.

11. The electronic device of claim 9, wherein a plurality of mounting grooves is defined in the support wall, the display panel comprises a plurality of extending portions correspondingly shaped to the plurality of mounting grooves, and each of the plurality of extending portions is received in each of the plurality of mounting grooves.

12. The electronic device of claim 11, wherein a height of the peripheral wall is greater than a height of the support wall along a direction substantially perpendicular to the bottom wall, such that the peripheral wall and the support wall cooperatively define a receiving groove, the electronic device further comprises a frame, and the frame is received in the receiving groove above the plurality of protection blocks and the plurality of extending portions of the display panel.

13. The electronic device of claim 12, wherein a size of the frame is substantially same as a size of the receiving groove.

14. The electronic device of claim 9, wherein the bottom wall is substantially rectangular, the support wall comprises four corners, each of the four corners defines the protection groove, the housing comprises four protection blocks, and each of the four protection blocks is securely fixed to the support wall in the protection groove.

15. The electronic device of claim 9, wherein a plurality of fixing holes is defined in a bottom surface of the protection groove, a plurality of engaging holes is defined in each of the plurality of protection blocks, the housing further comprises a plurality of fasteners, each of the plurality of fasteners comprises a fixing portion and an end portion connected to the fixing portion, the fixing portion passes through each of the plurality of engaging holes and is securely mounted in each of the plurality of fixing holes.

16. The electronic device of claim 15, wherein the end portion is entirely received in each of the plurality of engaging holes.

17. The electronic device of claim 9, wherein a thickness of each of the plurality of protection blocks is substantially equal to a depth of the protection groove.
